(19) United States
(12) Patent Application Publication
(10) Pub. No.: US 2024/0414940 A1
(43) Pub. Date: Dec. 12, 2024

(54) DISPLAY DEVICE

(71) Applicant: Sharp Display Technology Corporation, Kameyama City, Mie (JP)

(72) Inventors: Masaki MAEDA, Kameyama City, Mie (JP); Hajime IMAI, Kameyama City, Mie (JP); Yoshiharu HIRATA, Kameyama City, Mie (JP); Teruyuki UEDA, Kameyama City, Mie (JP); Tatsuya KAWASAKI, Kameyama City, Mie (JP); Tohru DAITOH, Kameyama City. Mie (JP)

(21) Appl. No.: 18/696,886

(22) PCT Filed: Dec. 6, 2021
(86) PCT No.: PCT/JP2021/044706

§ 371 Date: Mar. 28, 2024

(51) Int. Cl. H10K 59/121; H01L 27/12; H10K 59/131; H10K 59/80

(52) U.S. Cl. CPC H10K 59/1213; H10K 59/131; H10K 59/873; H01L 27/1218; H01L 27/124

(57) ABSTRACT

A display device includes: a base substrate; a thin-film transistor layer provided on the base substrate and having a first metal layer containing a copper film; and a light-emitting element layer provided on the thin-film transistor layer, and including a plurality of pixel electrodes, a plurality of light-emitting functional layers, and a common electrode, all of which are sequentially stacked on top of another and corresponding to a plurality of subpixels. A terminal unit includes a plurality of terminals formed of a same material as, and arranged in a same layer as, the first metal layer. Each of the pixel electrodes is formed of a second metal layer containing a silver film. On each of the terminals, a terminal protective layer formed of a transparent conductive film is provided.

### TECHNICAL FIELD

The disclosure relates to a display device.

### BACKGROUND ART

In recent years, light-emitting organic electroluminescence (EL) display devices using organic EL elements have attracted attention as a replacement for liquid crystal display devices. An organic EL display device is provided with a plurality of thin-film transistors (hereinafter also referred to as “TFTs”) for each of subpixels. A subpixel is a minimum unit of an image. Here, examples of a well-known semiconductor layer constituting a TFT include: a semiconductor layer made of polysilicon having high mobility; and a semiconductor layer made of oxide semiconductor such as In—Ga—Zn—O and exhibiting low current leakage.

For example, Patent Document 1 discloses an organic EL display device as a display device using a TFT substrate including a TFT having an oxide semiconductor layer.

### CITATION LIST

### Patent Literature

### [Patent Document 1] Japanese Patent No. 6311900

### SUMMARY

### Technical Problem

As to small-to-medium high-definition display devices operating on low power and including TFTs having semiconductor layers made of oxide semiconductors, a wiring structure has been proposed to include, for example, copper wiring lower in electrical resistance than aluminum wiring. Furthermore, an organic EL display device includes: a picture-frame region provided around a display region that displays an image; and a terminal unit provided to an end of the picture-frame region. In the terminal unit, a plurality of terminals are arranged. Here, In the organic EL display device, for example, when a silver film is etched and patterned to form a pixel electrode, a terminal included in the terminal unit and containing a copper film might be etched and lost.

The disclosure is conceived in view of the above problem, and sets out to reduce the risk that a terminal disposed in a terminal unit would be lost when a pixel electrode is formed.

### Solution to Problem

In order to achieve the above object, a display device according to the disclosure includes: a base substrate; a thin-film transistor layer provided on the base substrate and having a first metal layer containing a copper film; and a light-emitting element layer provided on the thin-film transistor layer, and including a plurality of pixel electrodes, a plurality of light-emitting functional layers, and a common electrode, all of which are sequentially stacked on top of another and corresponding to a plurality of subpixels included in a display region. The display region is surrounded with a picture-frame region. The picture-frame region has an end portion provided with a terminal unit. The terminal unit includes a plurality of terminals formed of a same material as, and arranged in a same layer as, the first metal layer. Each of the plurality of pixel electrodes is formed of a second metal layer containing a silver film. On each of the terminals, a terminal protective layer formed of a transparent conductive film is provided.

### Advantageous Effects of Disclosure

The disclosure can reduce the risk that a terminal disposed in a terminal unit T would be lost when a pixel electrode is formed.

### BRIEF DESCRIPTION OF DRAWINGS

FIG. 1 is a plan view of a schematic configuration of an organic EL display device according to a first embodiment of the disclosure.

FIG. 2 is a plan view of a display region of the organic EL display device according to the first embodiment of the disclosure.

FIG. 3 is a cross-sectional view of the display region of the organic EL display device according to the first embodiment of the disclosure.

FIG. 4 is an equivalent circuit diagram of a TFT layer included in the organic EL display device according to the first embodiment of the disclosure.

FIG. 5 is a cross-sectional view of an organic EL layer included in the organic EL display device according to the first embodiment of the disclosure.

FIG. 6 is a cross-sectional view of a terminal unit of the organic EL display device according to the first embodiment of the disclosure.

FIG. 7 is a cross-sectional view of a display region of an organic EL display device according to a second embodiment of the disclosure FIG. 7 corresponds to FIG. 3.

FIG. 8 is a cross-sectional view of a terminal unit of the organic EL display device according to the second embodiment of the disclosure FIG. 8 corresponds to FIG. 6.

### DESCRIPTION OF EMBODIMENTS

Embodiments of the disclosure will be described in detail below with reference to the drawings. Note that the disclosure shall not be limited to the embodiments below.

### First Embodiment

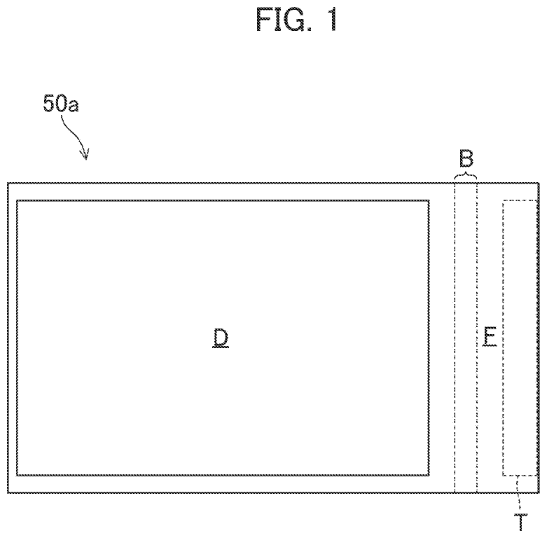

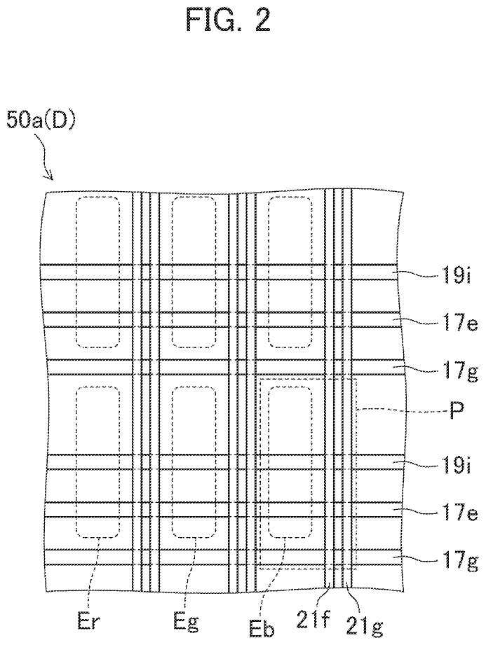

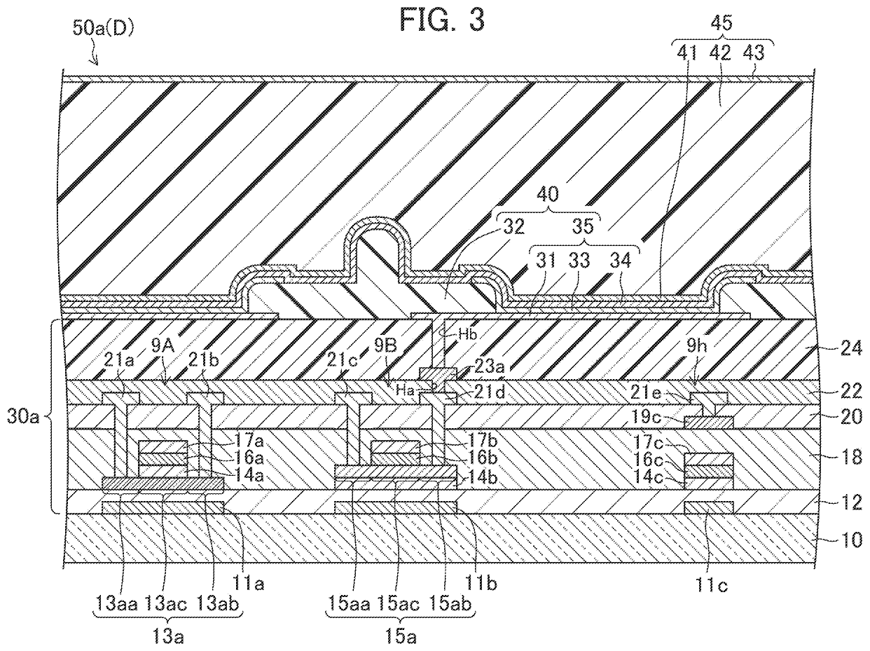

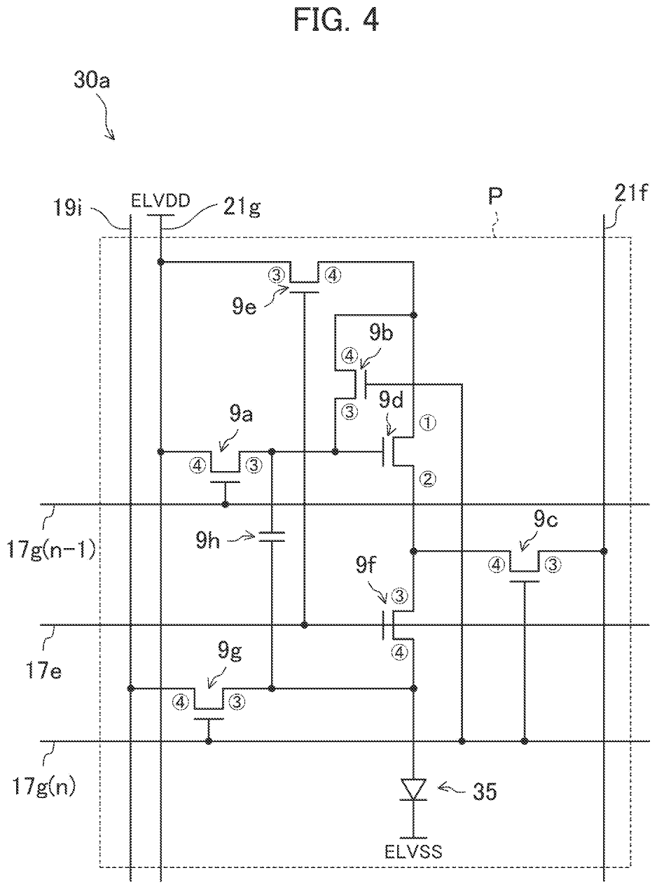

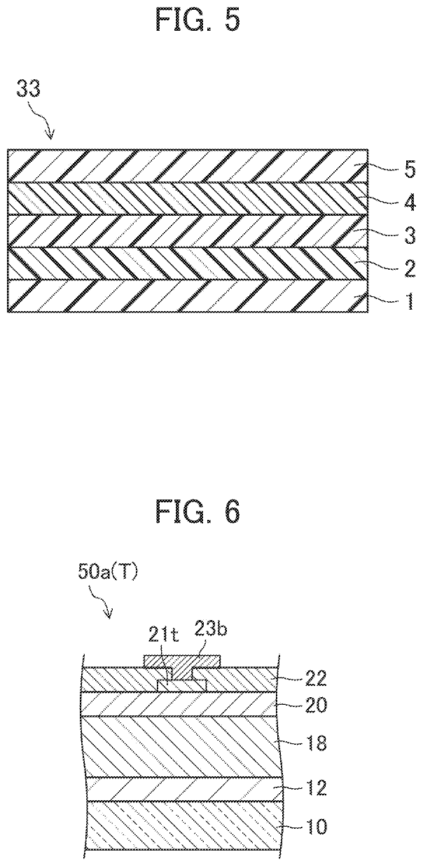

FIGS. 1 to 6 illustrate a first embodiment of a display device according to the disclosure. Note that, in the embodiments below, an organic EL display device including an organic EL element layer is exemplified as a display device including a light-emitting element layer. Here, FIG. 1 is a plan view of a schematic configuration of an organic EL display device 50a according to this embodiment. FIG. 2 is a plan view of a display region D of the organic EL display device 50a. FIG. 3 is a cross-sectional view of the display region D of the organic EL display device 50a. FIG. 4 is an equivalent circuit diagram of a TFT layer 30a included in the organic EL display device 50a. FIG. 5 is a cross-sectional view of an organic EL layer 33 included in the organic EL display device 50a. FIG. 6 is a cross-sectional view of a terminal unit T of the organic EL display device 50a.

As illustrated in FIG. 1, the organic EL display device 50a includes, for example: the display region D shaped into a rectangle and displaying an image; and a picture-frame region F provided around the display region D. Note that this embodiment exemplifies the display region D shaped into a rectangle. Examples of the rectangle include such substantial rectangles as a rectangle having arc-like sides, a rectangle having rounded corners, and a rectangle having partially notched sides.

The display region D illustrated in FIG. 2 includes a plurality of subpixels P arranged in a matrix. Moreover, in the display region D, as illustrated in FIG. 2, for example, subpixels P having red light-emitting regions Er for presenting red, subpixels P having green light-emitting regions Eg for presenting green, and subpixels P having blue light-emitting regions Eb for presenting blue are provided side by side. Note that, in the display region D, for example, neighboring three subpixels P each having one of a red light-emitting region Er, a green light-emitting region Eg, and a blue light-emitting region Eb constitute one pixel.

The picture-frame region F in FIG. 1 has a right end portion provided with the terminal unit T. Moreover, as illustrated in FIG. 1, the picture-frame region F includes a folding portion B between the display region D and the terminal unit T. The folding portion B, extending in one direction (in the vertical direction in the drawing), is foldable around a folding axis in the vertical direction in the drawing at an angle of 180° (foldable in a U-shape).

As illustrated in FIG. 3, the organic EL display device 50a includes: a glass substrate 10 provided as a base substrate; a TFT layer 30a provided on the glass substrate 10; an organic EL element layer 40 provided on the TFT layer 30a and serving as a light-emitting element layer; and a sealing film 45 provided to cover the organic EL element layer 40.

The glass substrate 10 is approximately, for example, 0.1 mm to 0.5 mm in thickness.

The TFT layer 30a illustrated in FIG. 3 includes: one first TFT 9A, six second TFTs 9B, and one capacitor 9h, all of which are provided on the glass substrate 10 for each of the subpixels P; and a protective insulating film 22 and a planarization film 24 both sequentially provided above each of the first TFT 9A, the second TFTs 9B, and the capacitor 9h. Here, the TFT layer 30a includes, as illustrated in FIG. 2, a plurality of gate lines 17g extending in parallel with one another in the horizontal direction in the drawing. Furthermore, the TFT layer 30a includes, as illustrated in FIG. 2, a plurality of light-emission control lines 17e extending in parallel with one another in the horizontal direction in the drawing. Moreover, the TFT layer 30a includes, as illustrated in FIG. 2, a plurality of second initialization power supply lines 19i extending in parallel with one another in the horizontal direction in the drawing. Note that, as illustrated in FIG. 2, the light-emission control lines 17e are provided side by side with the gate lines 17g and the second initialization power supply lines 19i. In addition, the TFT layer 30a includes, as illustrated in FIG. 2, a plurality of source lines 21f extending in parallel with one another in the vertical direction in the drawing. The plurality of source lines 21f serve as a first metal layer containing a copper film. Furthermore, the TFT layer 30a includes, as illustrated in FIG. 2, a plurality of power supply lines 21g extending in parallel with one another in the vertical direction in the drawing. The plurality of power supply lines 21g serve as the first metal layer. Note that, as illustrated in FIG. 2, the power supply lines 21g and the source lines 21f are provided side by side. Moreover, examples of the first metal layer include a monolayer copper film, and a multilayer film containing: either a titanium film or a molybdenum film (a lower layer); and a copper film (an upper layer).

As illustrated in FIG. 3, the first TFT 9A includes: a first semiconductor layer 13a; a first gate electrode 11a provided to the first semiconductor layer 13a toward the glass substrate 10 through a first gate insulating film 12; a second gate electrode 17a provided to the first semiconductor layer 13a across from the glass substrate 10 through a second gate insulating film 14a and a third gate insulating film 16a sequentially stacked from toward the glass substrate 10; a first interlayer insulating film 18 and a second interlayer insulating film 20 sequentially provided to cover the second gate electrode 17a; and a first terminal electrode 21a and a second terminal electrode 21b provided on the second interlayer insulating film 20 and spaced apart from each other.

The first semiconductor layer 13a is formed of, for example, an In—Ga—Zn—O-based oxide semiconductor. As illustrated in FIG. 3, the first semiconductor layer 13a includes: a first conductor region 13aa and a second conductor region 13ab defined to be spaced apart from each other; and a first channel region 13ac defined between the first conductor region 13aa and the second conductor region 13ab. Here, the In—Ga—Zn—O-based semiconductor is a ternary oxide of indium (In), gallium (Ga), and zinc (Zn), and a ratio (a composition ratio) of In to Ga to Zn shall not be limited to a particular ratio. Furthermore, the In—Ga—Zn—O-based semiconductor may be amorphous or crystalline. Note that the crystalline In—Ga—Zn—O-based semiconductor is preferably a crystalline In—Ga—Zn—O-based semiconductor in which the c-axis is oriented substantially perpendicular to the layer plane. Moreover, instead of the In—Ga—Zn—O-based semiconductor, the first semiconductor layer 13a may contain another oxide semiconductor. Examples of the other oxide semiconductor may include an In—Sn—Zn—O-based semiconductor (e.g., In₂O₃—SnO₂—ZnO; InSnZnO). Here, the In—Sn—Zn—O-based semiconductor is a ternary oxide of indium (In), tin (Sn), and zinc (Zn). In addition, other oxide semiconductors may include: an In—Al—Zn—O-based semiconductor; an In—Al—Sn—Zn—O-based semiconductor; a Zn—O-based semiconductor; an In—Zn—O-based semiconductor; a Zn—Ti—O-based semiconductor; a Cd—Ge—O-based semiconductor; a Cd—Pb—O-based semiconductor; cadmium oxide (CdO); a Mg—Zn—O-based semiconductor; an In—Ga—Sn—O-based semiconductor; an In—Ga—O-based semiconductor; a Zr—In—Zn—O-based semiconductor; a Hf—In—Zn—O-based semiconductor; an Al—Ga—Zn—O-based semiconductor; a Ga—Zn—O-based semiconductor; an In—Ga—Zn—Sn—O-based semiconductor; InGaO₃(ZnO)₅; zinc magnesium oxide (MgₓZn₁₋ₓO), and zinc cadmium oxide (CdₓZn₁₋ₓO). Note that the Zn—O-based semiconductor may be ZnO doped with one or more kinds of impurity elements among a group 1 element, a group 13 element, a group 14 element, a group 15 element, and a group 17 element. The Zn—O-based semiconductor may be in an amorphous state, in a polycrystalline state, or in a microcrystalline state in which an amorphous state and a polycrystalline state are mixed together. Alternatively. the Zn—O-based semiconductor does not have to be doped with any impurity element.

Each of the first gate insulating film 12, the second gate insulating film 14a (i.e., 14b to be described later), the third gate insulating film 16a (i.e., 16b to be described later), the first interlayer insulating film 18, the second interlayer insulating film 20, and the protective insulating film 22 is a monolayer inorganic insulating film or a multilayer inorganic insulating film made of such substances as, for example, silicon nitride, silicon oxide, and silicon oxide nitride. Here, for example, a silicon oxide film is included: in the first gate insulating film 12 and the second gate insulating film 14a (14b) at least toward the first semiconductor layer 13a; and in the second gate insulating film 14a (14b) and the third gate insulating film 16a (16b) at least toward a second semiconductor layer 15a to be described later.

As illustrated in FIG. 3, the first gate electrode 11a is provided to overlap with the first semiconductor layer 13a. The first gate electrode 11a controls, for example, characteristics of the first TFT 9A such as an S value (i.e., a rise coefficient in a subthreshold region).

As illustrated in FIG. 3, the second gate electrode 17a is provided to overlap with the first channel region 13ac of the first semiconductor layer 13a. The second gate electrode 17a controls conduction between the first conductor region 13aa and the second conductor region 13ab of the first semiconductor layer 13a.

As illustrated in FIG. 3, the first terminal electrode 21a and the second terminal electrode 21b are respectively and electrically connected to the first conductor region 13aa and the second conductor region 13ab of the first semiconductor layer 13a through a pair of contact holes formed in a multilayer film including the first interlayer insulating film 18, and the second interlayer insulating film 20. Here, the first terminal electrode 21a and the second terminal electrode 21b are formed of the same material as, and in the same layer as, the first metal layer.

As illustrated in FIG. 3, each of the second TFTs 9B includes: the second semiconductor layer 15a provided on the second gate insulating film 14b; a third gate electrode 11b provided to the second semiconductor layer 15a toward the glass substrate 10 through the first gate insulating film 12 and the second gate insulating film 14b; a fourth gate electrode 17b provided to the second semiconductor layer 15a across from the glass substrate 10 through a third gate insulating film 16b; the first interlayer insulating film 18 and the second interlayer insulating film 20 sequentially provided to cover the fourth gate electrode 17b; and a third terminal electrode 21c and a fourth terminal electrode 21d provided on the second interlayer insulating film 20 and spaced apart from each other.

Similar to the first semiconductor layer 13a, the second semiconductor layer 15a is formed of, for example, an In—Ga—Zn—O-based oxide semiconductor. As illustrated in FIG. 3, the second semiconductor layer 15a includes: a third conductor region 15aa and a fourth conductor region 15ab defined to be spaced apart from each other; and a second channel region 15ac defined between the third conductor region 15aa and the fourth conductor region 15ab.

As illustrated in FIG. 3, the third gate electrode 11b is provided to overlap with the second semiconductor layer 15a. The third gate electrode 11b controls, for example, characteristics of the second TFT 9B such as an S value.

As illustrated in FIG. 3, the fourth gate electrode 17b is provided to overlap with the second channel region 15ac of the second semiconductor layer 15a. The fourth gate electrode 17b controls conduction between the third conductor region 15aa and the fourth conductor region 15ab of the second semiconductor layer 15a.

As illustrated in FIG. 3, the third terminal electrode 21c and the fourth terminal electrode 21d are respectively and electrically connected to the third conductor region 15aa and the fourth conductor region 15ab of the second semiconductor layer 15a through a pair of contact holes formed in the multilayer film including the first interlayer insulating film 18 and the second interlayer insulating film 20. Here, the third terminal electrode 21c and the fourth terminal electrode 21d are formed of the same material as, and in the same layer as, the first metal layer.

In this embodiment, a drive TFT 9d to be described later is exemplified as the one first TFT 9A including the first semiconductor layer 13a exhibiting relatively low mobility. An initialization TFT 9a, a compensation TFT 9b, a write TFT 9c, a power supply TFT 9e, a light-emission control TFT 9f, and an anode discharge TFT 9g are also exemplified as the six second TFTs 9B each having the second semiconductor layer 15a exhibiting relatively high mobility. (See FIG. 4.) Note that, in the equivalent circuit diagram in FIG. 4, the first terminal electrode 21a and the second terminal electrode 21b of the TFT 9d are denoted by circled numerals 1 and 2, and the third terminal electrode 21c and the fourth terminal electrode 21d of each of the TFTs 9a, 9b, 9c, 9e, 9f, and 9g are denoted by circled numerals 3 and 4. Furthermore, the equivalent circuit diagram in FIG. 4 illustrates a pixel circuit of a subpixel P at the n-th row and the m-th column. The equivalent circuit diagram also partially includes a pixel circuit of a subpixel P at the (n−1)-th row and the m-th column. In addition, in the equivalent circuit diagram in FIG. 4, the power supply line 21g to supply a high power-supply voltage ELVDD also serves as a first initialization power supply line; however, the power supply line 21g and the first initialization power supply line may be provided separately. Moreover, the second initialization power supply line 19i receives, but not limited to, the same voltage as a low power-supply voltage ELVSS. The second initialization power supply line 19i may receive a voltage that differs from the low power-supply voltage ELVSS, and that turns OFF an organic EL element 35 to be described later.

As illustrated in FIG. 4, in each subpixel P, the initialization TFT 9a has: a gate electrode electrically connected to a gate line 17g(n−1) in a preceding stage (n−1 stage); the third terminal electrode electrically connected to a lower conductive layer of the capacitor 9h and to a gate electrode of the drive TFT 9d; and the fourth terminal electrode electrically connected to the power supply line 21g.

As illustrated in FIG. 4, in each subpixel P, the compensation TFT 9b has: a gate electrode electrically connected to a gate line 17g(n) in a corresponding stage (n-th stage); the third terminal electrode electrically connected to the gate electrode of the drive TFT 9d; and the fourth terminal electrode electrically connected to the first terminal electrode of the drive TFT 9d.

As illustrated in FIG. 4, in each subpixel P, the write TFT 9c has: a gate electrode electrically connected to the gate line 17g(n) in the corresponding stage (n-th stage); the third terminal electrode electrically connected to a corresponding source line 21f, and the fourth terminal electrode electrically connected to the second terminal electrode of the drive TFT 9d.

As illustrated in FIG. 4, in each subpixel P, the drive TFT 9d has: the gate electrode electrically connected to the third terminal electrode of each of the initialization TFT 9a and the compensation TFT 9b; the first terminal electrode electrically connected to the fourth terminal electrode of each of the compensation TFT 9b and the power supply TFT 9e; and the second terminal electrode electrically connected to the fourth terminal electrode of the write TFT 9c and to the third terminal electrode of the light-emission control TFT 9f. Here, the drive TFT 9d controls a current of the organic EL element 35.

As illustrated in FIG. 4, in each subpixel P, the power supply TFT 9e has: a gate electrode electrically connected to a light-emission control line 17e in the corresponding stage (n-th stage); the third terminal electrode electrically connected to the power supply line 21g; and the fourth terminal electrode electrically connected to the first terminal electrode of the drive TFT 9d.

As illustrated in FIG. 4, in each subpixel P, the light-emission control TFT 9f has: a gate electrode electrically connected to the light-emission control line 17e in the corresponding stage (n-th stage); the third terminal electrode electrically connected to the second terminal electrode of the drive TFT 9d; and the fourth terminal electrode electrically connected to a pixel electrode 31 of the organic EL element 35. The pixel electrode 31 and the organic EL element 35 will be described later.

As illustrated in FIG. 4, in each subpixel P, the anode discharge TFT 9g has: a gate electrode electrically connected to the gate line 17g(n) in the corresponding stage (n-th stage); the third terminal electrode electrically connected to the pixel electrode 31 of the organic EL element 35; and the fourth terminal electrode electrically connected to a second initialization power supply line 19i.

As illustrated in FIG. 3, the capacitor 9h includes: a lower conductive layer 17c formed of the same material as, and in the same layer as, the second gate electrode 17a and the fourth gate electrode 17b; the first interlayer insulating film 18 provided to cover the lower conductive layer 17c; and an upper conductive layer 19c provided on the first interlayer insulating film 18 to overlap with the lower conductive layer 17c, and formed of the same material as, and in the same layer as, the second initialization power supply line 19i. Moreover, as illustrated in FIG. 4, in each subpixel P, the capacitor 9h has: the lower conductive layer 17c electrically connected to the gate electrode of the drive TFT 9d and to the third terminal electrode of each of the initialization TFT 9a and the compensation TFT 9b; and the upper conductive layer 19c electrically connected to the third terminal electrode of the anode discharge TFT 9g, to the fourth terminal electrode of the light-emission control TFT 9f, and to the pixel electrode 31 of the organic EL element 35. Here, the conductive layer 11c is provided to the lower conductive layer 17c toward the glass substrate 10 through the first gate insulating film 12, the second gate insulating film 14c, and the third gate insulating film 16c. Note that the conductive layer 11c is formed of the same material as, and in the same layer as, the first gate electrode 11a and the third gate electrode 11b. Furthermore, as illustrated in FIG. 3, the upper conductive layer 19c is electrically connected to a conductive layer 21e formed of the same material as, and in the same layer as, the first metal layer.

The planarization film 24 has a flat surface in the display region D. The planarization film 24 is made of such a material as, for example, an organic resin material such as polyimide resin or acrylic resin, or a polysiloxane-based spin-on-glass (SOG) material.

As illustrated in FIG. 3, the organic-EL-element layer 40 includes a plurality of the pixel electrodes 31, an edge cover 32 provided in common, a plurality of the organic EL layers 33, and a common electrode 34, all of which are sequentially stacked on top of another above the TFT layer 30a and corresponding to the plurality of subpixels P. Here, as illustrated in FIG. 3, the organic EL element layer 35 includes: a pixel electrode 31; an organic EL layer 33; and the common electrode 34, each of which is sequentially stacked on top of another above the planarization film 24 of the TFT layer 30a.

As illustrated in FIG. 3, the pixel electrode 31 is electrically connected to the fourth terminal electrode 21d of the light-emission control TFT 9f in each subpixel P, through: a contact hole Ha formed in the protective insulating film 22; a relay electrode 23a provided between the protective insulating film 22 and the planarization film 24; and a contact hole Hb formed in the planarization film 24. Note that the relay electrode 23a is formed of the same material as, and in the same layer as, a terminal protective layer 23b to be described later. Furthermore, the pixel electrode 31 has a function of injecting holes into the organic EL layer 33. Moreover, the pixel electrode 31 is preferably formed of a material having a large work function to improve efficiency in injecting the holes into the organic EL layer 33. Here, the pixel electrode 31 is formed of a second metal layer specifically containing a silver film. Note that examples of the second metal layer include: a silver monolayer film; and a multilayer film having a silver film sandwiched with conductive oxide films made of such materials as tin oxide (SnO), zinc oxide (ZnO), indium tin oxide (ITO), and indium zinc oxide (IZO).

The edge cover 32 illustrated in FIG. 3 is provided in a grid to cover a peripheral end portion of each pixel electrode 31. Here, the edge cover 32 is made of, for example, an organic resin material such as polyimide resin or acrylic resin, or a polysiloxane-based SOG material.

The organic EL layer 33 is provided as a light-emitting functional layer. As illustrated in FIG. 5, the organic EL layer 33 includes: a hole injection layer 1; a hole transport layer 2; a light-emitting layer 3; an electron transport layer 4; and an electron injection layer 5, all of which are sequentially stacked on top of another above the pixel electrode 31.

The hole injection layer 1 is also referred to as an anode buffer layer. The hole injection layer 1 has a function of approximating energy levels between the pixel electrode 31 and the organic EL layer 33 to improve efficiency in injecting the holes from the pixel electrode 31 into the organic EL layer 33. Here, examples of a material forming the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has a function of improving efficiency in transporting the holes from the pixel electrode 31 to the organic EL layer 33. Here, examples of a material forming the hole transport layer 2 include a porphyrin derivative, an aromatic tertiary amine compound, a styrylamine derivative, polyvinyl carbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, zinc selenide, and zinc selenide.

The light-emitting layer 3 is a region where the holes and the electrons are respectively injected from the pixel electrode 31 and the common electrode 34, and recombine together, when a voltage is applied with the pixel electrode 31 and the common electrode 34. Here, the light-emitting layer 3 is formed of a material having high light-emission efficiency. Examples of the material forming the light-emitting layer 3 include a metal oxinoid compound [8-hydroxyquinoline metal complex], a naphthalene derivative, an anthracene derivative, a diphenylethylene derivative, a vinylacetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rhodamine derivative, an aquizine derivative, phenoxazone, a quinacridone derivative, rubrene, poly-p-phenylenevinylene, and polysilane.

The electron transport layer 4 has a function of efficiently moving the electrons to the light-emitting layer 3. Here, examples of a material forming the electron transport layer 4 include, as organic compounds, an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has a function of approximating energy levels between the common electrode 34 and the organic EL layer 33 to improve efficiency in injecting the electrons from the common electrode 34 into the organic EL layer 33. Such a function can decrease a drive voltage of the organic EL element 35. Note that the electron injection layer 5 is also referred to as a cathode buffer layer. Here, examples of a material forming the electron injection layer 5 include: inorganic alkali compounds such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the common electrode 34 is provided in common to all the subpixels P to cover each organic EL layer 33 and the edge cover 32. Moreover, the common electrode 34 has a function of injecting the electrons into the organic EL layer 33. Furthermore, the common electrode 34 is preferably formed of a material having a small work function to improve efficiency in injecting the electrons into the organic EL layer 33. Here, examples of the material forming the common electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Moreover, the common electrode 34 may be formed of an alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), or lithium fluoride (LiF)/calcium (Ca)/aluminum (Al). Furthermore, the common electrode 34 may be formed of a conductive oxide such as tin oxide (SnO), zinc oxide (ZnO), indium tin oxide (ITO), or indium zinc oxide (IZO). In addition, the common electrode 34 may be formed of a plurality of layers made of the above materials and stacked on top of another. Note that examples of the material having a small work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As illustrated in FIG. 3, the sealing film 45 is provided to cover the common electrode 34, and includes: a first inorganic sealing film 41; an organic sealing film 42; and a second inorganic sealing film 43, all of which are sequentially stacked on top of another above the common electrode 34. The sealing film 45 has a function of protecting the organic EL layer 33 in the organic EL element layer 35 from moisture and oxygen.

Each of the first inorganic sealing film 41 and the second inorganic sealing film 43 is formed of such an inorganic insulating film as, for example, a silicon nitride film, a silicon oxide film, or a silicon oxynitride film.

The organic sealing film 42 is formed of such an organic resin material as, for example, acrylic resin, epoxy resin, silicone resin, polyurea resin, parylene resin, polyimide resin, or polyamide resin. Note that the picture-frame region F of the organic EL display device 50a is provided with: a first dam wall shaped into a picture frame and provided around the display region D, in order to keep an ink, forming the organic sealing film 42, from spreading; and a second dam wall shaped into a picture frame and provided around the first dam wall.

Furthermore, as illustrated in FIG. 6, the organic EL display device 50a includes a plurality of terminals 21t included in the terminal unit T of the picture-frame region F and arranged in a line in a direction in which the terminal unit T extends (i.e., in the vertical direction in FIG. 1). Here, the terminals 21t are formed of the same material as, and in the same layer as, the first metal layer. Moreover, on the terminals 21t, as illustrated in FIG. 6, the terminal protective layer 23b is provided. The terminal protective layer 23b is formed of a transparent conductive film made of a substance such as indium tin oxide (ITO). In addition, at the display region D, each of the terminals 21t is electrically connected to display wires such as the gate line 17g, the light-emission control line 17e, the source line 21f, the power supply line 21g, and the second initialization power supply line 19i.

As to the organic EL display device 50a having the above configuration, in each subpixel P, when the light-emission control line 17e is first selected to be in an inactive state, the organic EL element 35 is in a non-light-emission state. In the non-light-emission state, the gate line 17g(n−1) in the preceding stage is selected. Through the gate line 17g(n−1), a gate signal is input into the initialization TFT 9a such that the initialization TFT 9a turns ON. Hence, the high power-supply voltage ELVDD of the power supply line 21g is applied to the capacitor 9h, and the drive TFT 9d turns ON. Thus, charges of the capacitor 9h are discharged, and a voltage to be applied to the gate electrode of the drive TFT 9d is initialized. Next, when the gate line 17g(n) of the corresponding stage is selected to be in the active state, the compensation TFT 9b and the write TFT 9c turn ON, and a predetermined voltage corresponding to a source signal to be transmitted through the corresponding source line 21f is written into the capacitor 9h through the drive TFT 9d connected to a diode. Simultaneously, the anode discharge TFT 9g turns ON, and an initialization signal is applied through the second initialization power supply line 19i to the pixel electrode 31 of the organic EL element 35. Hence, the charges stored in the pixel electrode 31 are reset. After that, the light-emission control line 17e is selected, and the power supply TFT 9e and the light-emission control TFT 9f turn ON. Hence, a drive current corresponding to the voltage applied to the gate electrode of the drive TFT 9d is supplied from the power supply line 21g to the organic EL element 35. Thus, in each subpixel P, the organic EL element 35 emits light the luminance of which corresponds to the drive current. This is how the organic EL display device 50a displays an image.

Described next will be a method for producing the organic EL display device 50a of this embodiment. Note that the method for producing the organic EL display device 50a includes: a TFT-layer forming step; an organic-EL-element-layer forming step; and a sealing-film forming step.

### TFT-Layer Forming Step

First, for example, on the glass substrate 10, for example, a titanium film (approximately 30 nm in thickness) and a copper film (approximately 300 nm in thickness) are deposited sequentially by sputtering. After that, the multilayer metal film including these films is patterned to form the first gate electrode 11a, the second gate electrode 11b, and the conductive layer 11c.

Then, on a substrate surface of the first gate electrode 11a, for example, a silicon nitride film (approximately 100 nm in thickness) and a silicon oxide film (approximately 250 nm in thickness) are deposited sequentially by the plasma chemical vapor deposition (CVD). Hence, the first gate insulating film 12 is formed.

Then, on a substrate surface of the first gate insulating film 12, for example, an oxide semiconductor film (approximately 50 nm in thickness), formed of, for example, InGaZnO₄, is deposited by sputtering. After that, the oxide semiconductor film is patterned to form, for example, the first semiconductor layer 13a.

Furthermore, on a substrate surface of the first semiconductor layer 13a, as illustrated in FIG. 3, for example, a silicon oxide film (approximately 50 nm in thickness) is deposited by the plasma CVD. Then, an oxide semiconductor film formed of, for example, InGaZnO₄, is deposited by sputtering. After that, the oxide semiconductor film is patterned to form, for example, the second semiconductor layer 15a.

Then, on a substrate surface of the second semiconductor layer 15a, for example, a silicon oxide film (approximately 150 nm in thickness) and a copper film (approximately 300 nm in thickness) are sequentially deposited respectively by the plasma CVD and sputtering. After that, the multilayer metal film including these films is patterned to form, for example, the gate line 17g, the light-emission control line 17e, the second gate electrode 17a, the fourth gate electrode 17b, and the lower conductive layer 17c. Then, the exposed silicon oxide film is removed, so that the second gate insulating films 14a, 14b, and 14c, and the third gate insulating films 16a, 16b, and 16c are formed.

After that, on substrate surface of the second gate insulating film 14a, for example, a silicon oxide film (approximately 300 nm in thickness) is deposited by the plasma CVD to form the first interlayer insulating film 18.

Furthermore, on a substrate surface of the first interlayer insulating film 18, a titanium film (approximately 30 nm in thickness) and a copper film (approximately 300 nm in thickness) are sequentially deposited by sputtering. After that, the multilayer metal film including these films is patterned to form, for example, the upper conductive layer 19c and the second initialization power supply line 19i.

Then, on a substrate surface of the upper conductive layer 19c, for example, an inorganic insulating film such as a silicon nitride film (approximately 150 nm in thickness) is deposited by the plasma CVD. The inorganic insulating film and the silicon oxide film below the inorganic insulating film are patterned to form the second interlayer insulating film 20.

Then, on a substrate surface of the second interlayer insulating film 20, for example, a titanium film (approximately 30 nm in thickness) and a copper film (approximately 200 nm in thickness) are sequentially deposited by sputtering. After that, the multilayer metal film including these films is patterned to form, for example, the source line 17f, the power supply line 21g, the first terminal electrode 21a, the second terminal electrode 21b, the third terminal electrode 21c, the fourth terminal electrode 21d, the conductive layer 21e, and the terminal 21t.

Furthermore, on a substrate surface of the first terminal electrode 21a, for example, a silicon oxide film (approximately 100 nm in thickness) and a silicon nitride film (approximately 50 nm in thickness) are sequentially deposited by the plasma CVD. After that, the multilayer inorganic insulating film including these films are patterned to form the protective insulating film 22.

After that, on a substrate surface of the protective insulating film 22, for example, a transparent conductive film (approximately 70 nm in thickness) such as an ITO film is deposited by sputtering. After that, the transparent conductive film is patterned to form the relay electrode 23a and the terminal protective layer 23b.

Finally, a substrate surface of the relay electrode 23a is coated with, for example, a polyimide-based photosensitive resin film (approximately 2 μm in thickness) by spin coating or slit coating. After that, the coating film is pre-baked, exposed to light, developed, and post-baked to form the planarization film 24.

As described above, the TFT layer 30a is successfully formed.

### Organic-EL-Element-Layer Forming Step (Light-Emitting-Element-Layer Forming Step)

On the planarization film 24 of the TFT layer 30a formed at the TFT-layer forming step, the pixel electrode 31, the edge cover 32, the organic EL layer 33 (including the hole injection layer 1, the hole transport layer 2, the light-emitting layer 3, the electron transport layer 4, and the electron injection layer 5), and the common electrode 34 are formed, using a known technique. Hence, the organic EL element layer 40 is formed. Here, in forming the pixel electrode 31 made of the second metal layer containing a silver film, for example, a multilayer film including an ITO film (approximately 10 nm in thickness), a silver film (approximately 100 nm in thickness), and an ITO film (approximately 10 nm in thickness) is etched with an etchant containing phosphoric acid, acetic acid, and nitric acid. The terminal protective layer 23b is provided on each of the terminals 21t included in the terminal unit T and containing a copper film (susceptible to etching with the etchant). Such a feature keeps the terminals 21t from being etched.

### Sealing-Film Forming Step

First, on a substrate surface of the organic EL element layer 40 formed at the organic-EL-element-layer forming step, an inorganic insulating film such as, for example, a silicon nitride film, a silicon oxide film, or a silicon oxynitride film is deposited by the plasma CVD, using a mask. Hence, the first inorganic sealing film 41 is formed.

Then, on a substrate surface of the first inorganic sealing film 41, for example, an organic resin material such as acrylic resin is deposited by inkjet printing. Hence, the organic sealing film 42 is formed.

Finally, on a substrate surface of the organic sealing film 42, an inorganic insulating film such as, for example, a silicon nitride film, a silicon oxide film, or a silicon oxynitride film is deposited by the plasma CVD, using a mask, to form the second inorganic sealing film 43. Hence, the sealing film 45 is formed.

As can be seen, the organic EL display device 50a of this embodiment is successfully produced.

As described above, as to the organic EL display device 50a of this embodiment, even if the terminals 21t arranged in the terminal unit T of the picture-frame region F are formed of the same material as, and in the same layer as, the first metal layer containing a copper film, the terminal protective layer 23b formed of a transparent conductive film is provided on each of the terminals 21t. Hence, even if the metal film containing a silver film is etched to form the pixel electrode 31 at the organic-EL-element-layer forming step, the terminals 21t are less likely to be etched. Such a feature can reduce the risk that the terminals 21t disposed in the terminal unit T would be lost when the pixel electrode 31 is formed.

### Second Embodiment

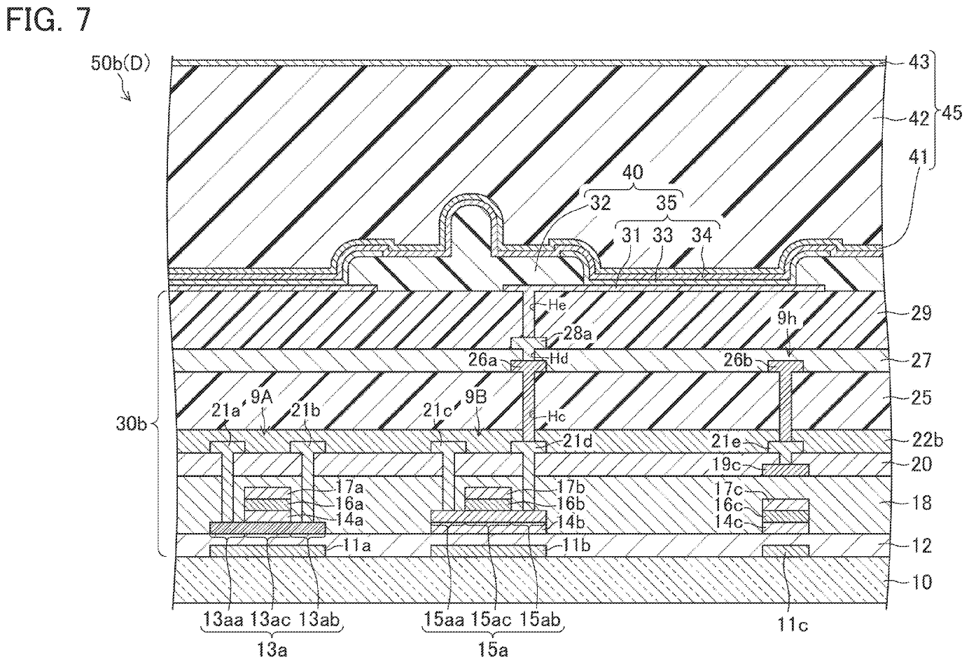

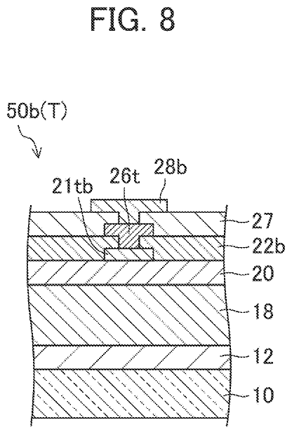

FIGS. 7 and 8 illustrate a display device according to a second embodiment of the disclosure. Here, FIG. 7 is a cross-sectional view of the display region D of an organic EL display device 50b according to this embodiment. FIG. 7 corresponds to FIG. 3. Furthermore, FIG. 8 is a cross-sectional view of the terminal unit T of the organic EL display device 50b. FIG. 8 corresponds to FIG. 6. Note that, in the embodiment below, like reference signs designate identical constituent features throughout FIGS. 1 to 6. These constituent features will not be elaborated upon here.

The first embodiment describes, as an example, the organic EL display device 50a provided with copper wiring including three wiring layers; namely, a first wiring layer such as the first gate electrode 11a, a second wiring layer such as the second gate electrode 17a, and a third wiring layer such as the first terminal electrode 21a. This embodiment describes, as an example, the organic EL display device 50b provided with copper wiring including four wiring layers; namely, the first wiring layer such as the first gate electrode 11a, the second wiring layer such as the second gate electrode 17a, the third wiring layer such as the first terminal electrode 21a, and a fourth wiring layer such as a first relay electrode 26a.

Similar to the organic EL display device 50a of the first embodiment, the organic EL display device 50b includes, for example: the display region D shaped into a rectangle; and the picture-frame region F provided around the display region D.

As illustrated in FIG. 7, the organic EL display device 50b includes: the glass substrate 10 serving as a base substrate; a TFT layer 30b provided on the glass substrate 10; the organic EL element layer 40 provided on the TFT layer 30b and serving as a light-emitting element layer; and the sealing film 45 provided to cover the organic EL element layer 40.

The TFT layer 30b illustrated in FIG. 7 includes: one first TFT 9A, six second TFTs 9B, and one capacitor 9h, all of which are provided on the glass substrate 10 for each of the subpixels P; and a first protective insulating film 22b, a first planarization film 25, a second protective insulating film 27, and a second planarization film 29, all of which are sequentially provided above each of the first TFT 9A, the second TFTs 9B, and the capacitor 9h. Here, similar to the TFT layer 30a included in the organic EL display device 50a of the first embodiment, the TFT layer 30b includes the plurality of gate lines 17g, the plurality of light-emission control lines 17e, the plurality of second initialization power supply lines 19i, the plurality of source lines 21f, and the plurality of power supply lines 21g. Note that, in the first embodiment, such lines as the source line 21f and the power supply line 21g are provided as the first metal layer containing a copper film. In this embodiment, such lines as the source line 21f and the power supply line 21g are provided as a third metal layer containing a copper film, and such an electrode as the first relay electrode 26a to be described later is provided as the first metal layer containing a copper film.

The first protective insulating film 22b and the second protective insulating film 27 are formed of such an inorganic insulating film as, for example, a silicon nitride film, a silicon oxide film, or a silicon oxynitride film. Alternatively, the first protective insulating film 22b and the second protective insulating film 27 are formed of a multilayer film including these films.

Here, in this embodiment, similar to the TFT layer 30a included in the organic EL display device 50a of the first embodiment, the drive TFT 9d is provided as the one first TFT 9A including the first semiconductor layer 13a exhibiting relatively low mobility, and the initialization TFT 9a, the compensation TFT 9b, the write TFT 9c, the power supply TFT 9e, the light-emission control TFT 9f, and the anode discharge TFT 9g are provided as the six second TFTs 9B each having the second semiconductor layer 15a exhibiting relatively high mobility.

Similar to the TFT layer 30a included in the organic EL display device 50a of the first embodiment, the capacitor 9h includes, for example, as illustrated in FIG. 7: the lower conductive layer 17c formed of the same material as, and in the same layer as, the second gate electrode 17a and the fourth gate electrode 17b; the first interlayer insulating film 18 provided to cover the lower conductive layer 17c; and the upper conductive layer 19c provided on the first interlayer insulating film 18 to overlap with the lower conductive layer 17c, and formed of the same material as, and in the same layer as, the second initialization power supply line 19i. Here, as illustrated in FIG. 7, the upper conductive layer 19c is electrically connected to the conductive layer 21e formed of the same material as, and in the same layer as, the third metal layer. Furthermore, as illustrated in FIG. 7, the conductive layer 21e is electrically connected to a conductive layer 26b formed of the same material as, and in the same layer as, the first metal layer.

Each of the first planarization film 25 and the second planarization film 29 has a flat surface in the display region D. The first planarization film 25 and the second planarization film 29 are made of such a material as, for example, an organic resin material such as polyimide resin or acrylic resin, or a polysiloxane-based SOG material.

As illustrated in FIG. 7, each of the pixel electrodes 31 included in the organic-EL-element layer 40 is electrically connected to the fourth terminal electrode 21d of the light-emission control TFT 9f for each subpixel P, through: a contact hole Hc formed in the first protective insulating film 22b and the first planarization film 25; a contact hole Hd formed in the second protective insulating film 27; a second relay electrode 28a provided between the second protective insulating film 27 and the second planarization film 29; and a contact hole He formed in the second planarization film 29. Note that the second relay electrode 28a is formed of the same material as, and in the same layer as, a terminal protective layer 28b to be described later.

Furthermore, as illustrated in FIG. 8, the organic EL display device 50b includes a plurality of terminals 26t included in the terminal unit T of the picture-frame region F and arranged in a line in a direction in which the terminal unit T extends (i.e., in the vertical direction in FIG. 1). Here, the terminals 26t are formed of the same material as, and in the same layer as, the first metal layer of this embodiment. Moreover, on the terminals 26t, as illustrated in FIG. 8, the terminal protective layer 28b is provided. The terminal protective layer 28b is formed of a transparent conductive film made of a substance such as indium tin oxide (ITO). Furthermore, as illustrated in FIG. 8, each of the terminals 26t includes a terminal lower portion 21tb provided toward the glass substrate 10, formed of the same material as, and in the same layer as, the third metal layer of this embodiment, and electrically connected to the terminal 26t. In addition, at the display region D, each of the terminals 26t is electrically connected to display wires such as the gate line 17g, the light-emission control line 17e, the source line 21f, the power supply line 21g, and the second initialization power supply line 19i.

The organic EL display device 50b in the above configuration is similar to the organic EL display device 50a of the first embodiment. In each subpixel P, the organic EL element 35 emits light the luminance of which corresponds to the drive current. This is how the organic EL display device 50b displays an image.

Described next will be a method for producing the organic EL display device 50b of this embodiment. Note that the method for producing the organic EL display device 50b includes: a TFT-layer forming step; an organic-EL-element-layer forming step; and a sealing-film forming step. The organic-EL-element layer forming step and the sealing-film forming step are substantially the same as those of the method for producing the organic EL display device 50a of the first embodiment. Hence, described here will be the TFT-layer forming step.

### TFT-Layer Forming Step

First, at the TFT-layer forming step for the organic EL display device 50a of the first embodiment, a substrate surface of the protective insulating film 22 (i.e., the first protective insulating film 22b) is coated with, for example, a polyimide-based photosensitive resin film (approximately 2 μm in thickness) by spin coating or slit coating. After that, the coating film is pre-baked, exposed to light, developed, and post-baked to form the first planarization film 25.

Next, the first protective insulating film 22b exposed from the first planarization film 25 is removed, and the contact hole Hc is formed.

Then, on a substrate surface of the contact hole Hc, for example, an ITO film (approximately 70 nm in thickness) and a copper film (approximately 200 nm in thickness) are sequentially deposited by sputtering. After that, the multilayer film including these films is patterned to form the first relay electrode 26a, the conductive layer 26b, and the terminal 26t.

Furthermore, on a substrate surface of the first relay electrode 26a, for example, an inorganic insulating film such as a silicon nitride film (approximately 200 nm in thickness) is deposited by the plasma CVD. After that, the inorganic insulating film is patterned to form the second protective insulating film 27.

After that, on a substrate surface of the second protective insulating film 27, for example, a transparent conductive film (approximately 70 nm in thickness) such as an ITO film is deposited by sputtering. After that, the transparent conductive film is patterned to form the second relay electrode 28a and the terminal protective layer 28b.

Finally, a substrate surface of the second relay electrode 28a is coated with, for example, a polyimide-based photosensitive resin film (approximately 2 μm in thickness) by spin coating or slit coating. After that, the coating film is pre-baked, exposed to light, developed, and post-baked to form the second planarization film 29.

As described above, the TFT layer 30b is successfully formed.

After that, the organic-EL-element-layer forming step and the sealing-film forming step for the organic EL display device 50a of the first embodiment are carried out. Hence, the organic EL display device 50b of this embodiment is successfully produced. Note that, when the pixel electrode 31 made of the second metal layer containing a silver film is formed at the organic-EL-element-layer forming step, for example, a multilayer film including an ITO film, a silver film, and an ITO film is etched with an etchant containing phosphoric acid, acetic acid, and nitric acid. The terminal protective layer 28b is provided on each of the terminals 26t included in the terminal unit T and containing a copper film (susceptible to etching with the etchant). Such a feature keeps the terminals 26t from being etched.

As described above, as to the organic EL display device 50b of this embodiment, even if the terminals 26t arranged in the terminal unit T of the picture-frame region F are formed of the same material as, and in the same layer as, the first metal layer containing a copper film, the terminal protective layer 28b formed of a transparent conductive film is provided on each of the terminals 26t. Hence, even if the metal film containing a silver film is etched to form the pixel electrode 31 at the organic-EL-element-layer forming step, the terminals 26t are less likely to be etched. Such a feature can reduce the risk that the terminals 26t disposed in the terminal unit T would be lost when the pixel electrode 31 is formed.

### Other Embodiments

The above embodiments exemplify organic EL display devices in which each subpixel P is provided with one first TFT 9A and six second TFTs 9B. However, the disclosure is applicable to display devices such as an organic EL display device in which each subpixel P is provided with seven first TFTs 9A, and a second TFT 9B is provided to a circuit disposed around picture-frame region F.

Furthermore, in each of the above embodiments, the exemplified organic EL display device includes a glass substrate serving as a base substrate. Alternatively, the disclosure is also applicable to display devices such as an organic EL display device including a resin substrate serving as a base substrate.

Moreover, in each of the above embodiments, the exemplified organic EL layer has a multilayer structure including five layers such as a hole injection layer, a hole transport layer, a light-emitting layer, an electron transport layer, and an electron injection layer. Alternatively, the organic EL layer may have a multilayer structure including three layers such as, for example, a hole-injection-and-hole-transport layer, a light-emitting layer, and an electron-transport-and-electron-injection layer.

Moreover, in each of the above embodiments, the exemplified organic EL display device includes a pixel electrode as an anode and a common electrode as a cathode. The disclosure is also applicable to an organic EL display device whose multilayer structure of the organic EL layer is inverted, and the pixel electrode is a cathode and the common electrode is an anode.

In addition, in each of the embodiments, the organic EL display device is exemplified as a display device. The disclosure is applicable to a display device including a plurality of light-emitting elements driven by currents. For example, the disclosure is applicable to a display device including quantum-dot light-emitting diodes (QLEDs); that is, light-emitting elements including layers containing quantum dots.

### INDUSTRIAL APPLICABILITY

As described above, the disclosure is useful for a light-emitting display device.

1. A display device, comprising:
a base substrate;
a thin-film transistor layer provided on the base substrate and having a first metal layer containing a copper film; and
a light-emitting element layer provided on the thin-film transistor layer, and including a plurality of pixel electrodes, a plurality of light-emitting functional layers, and a common electrode, all of which are sequentially stacked on top of another and corresponding to a plurality of subpixels included in a display region,
the display region being surrounded with a picture-frame region,
the picture-frame region having an end portion provided with a terminal unit,
the terminal unit including a plurality of terminals formed of a same material as, and arranged in a same layer as, the first metal layer, and
each of the plurality of pixel electrodes being formed of a second metal layer containing a silver film,
wherein, on each of the terminals, a terminal protective layer formed of a transparent conductive film is provided,
the thin-film transistor layer includes a first thin-film transistor having a first semiconductor layer provided for each of the plurality of subpixels and formed of an oxide semiconductor, and
the first thin-film transistor includes: the first semiconductor layer including a first conductor region and a second conductor region defined to be spaced apart from each other; a first gate electrode provided to the first semiconductor layer toward the base substrate through a first gate insulating film; a second gate electrode provided to the first semiconductor layer across from the base substrate through a second gate insulating film and a third gate insulating film sequentially stacked from toward the base substrate; an interlayer insulating film provided to cover the second gate electrode; and a first terminal electrode and a second terminal electrode provided on the interlayer insulating film and spaced apart from each other, formed of a same material as, and in a same layer as, the first metal layer, and respectively and electrically connected to the first conductor region and the second conductor region.

2. (canceled)

3. (canceled)

4. The display device according to claim 1,
wherein the thin-film transistor layer includes a second thin-film transistor having a second semiconductor layer provided for each of the plurality of subpixels and formed of an oxide semiconductor.

5. The display device according to claim 4,
wherein the second thin-film transistor includes: the second semiconductor layer including a third conductor region and a fourth conductor region defined to be spaced apart from each other and provided on the second gate interlayer insulating film; a third gate electrode provided to the second semiconductor layer toward the base substrate through the first gate insulating film and the second gate insulating film; a fourth gate electrode provided to the second semiconductor layer across from the base substrate through the third gate insulating film; the interlayer insulating film provided to cover the fourth gate electrode; and a third terminal electrode and a fourth terminal electrode provided on the interlayer insulating film and spaced apart from each other, formed of a same material as, and in a same layer as, the first metal layer, and respectively and electrically connected to the third conductor region and the fourth conductor region.

6. The display device according to claim 5,
wherein the thin-film transistor layer includes: a protective insulating film provided on the first terminal electrode, the second terminal electrode, the third terminal electrode, and the fourth terminal electrode; and a planarization film provided on the protective insulating film, and
the third terminal electrode and the fourth terminal electrode are electrically connected to a corresponding pixel electrode included in the plurality of pixel electrodes, through: a contact hole formed in the protective insulating film; a relay electrode provided between the protective insulating film and the planarization film, and formed of a same material as, and in a same layer as, the terminal protective layer; and a contact hole formed in the planarization film.

7. A display device, comprising:
a base substrate;
a thin-film transistor layer provided on the base substrate and having a first metal layer containing a copper film; and
a light-emitting element layer provided on the thin-film transistor layer, and including a plurality of pixel electrodes, a plurality of light-emitting functional layers, and a common electrode, all of which are sequentially stacked on top of another and corresponding to a plurality of subpixels included in a display region,
the display region being surrounded with a picture-frame region,
the picture-frame region having an end portion provided with a terminal unit,
the terminal unit including a plurality of terminals formed of a same material as, and arranged in a same layer as, the first metal layer, and
each of the plurality of pixel electrodes being formed of a second metal layer containing a silver film,
wherein, on each of the terminals, a terminal protective layer formed of a transparent conductive film is provided,
the thin-film transistor layer includes a first thin-film transistor having a first semiconductor layer provided for each of the plurality of subpixels and formed of an oxide semiconductor,
the thin-film transistor layer includes a third metal layer containing a copper film and provided to the first metal layer toward the base substrate,
each of the plurality of terminals includes a terminal lower portion provided toward the base substrate, formed of a same material as, and in a same layer as, the third metal layer, and electrically connected to the terminal, and
the first thin-film transistor includes: the first semiconductor layer including a first conductor region and a second conductor region defined to be spaced apart from each other; a first gate electrode provided to the first semiconductor layer toward the base substrate through a first gate insulating film; a second gate electrode provided to the first semiconductor layer across from the base substrate through a second gate insulating film and a third gate insulating film sequentially stacked from toward the base substrate; an interlayer insulating film provided to cover the second gate electrode; and a first terminal electrode and a second terminal electrode provided on the interlayer insulating film and spaced apart from each other; formed of a same material as, and in a same layer as, the third metal layer, and respectively and electrically connected to the first conductor region and the second conductor region.

8. (canceled)

9. The display device according to claim 7,
wherein the thin-film transistor layer includes a second thin-film transistor having a second semiconductor layer provided for each of the plurality of subpixels and formed of an oxide semiconductor.

10. The display device according to claim 9,
wherein the second thin-film transistor includes: the second semiconductor layer including a third conductor region and a fourth conductor region defined to be spaced apart from each other and provided on the second gate interlayer insulating film; a third gate electrode provided to the second semiconductor layer toward the base substrate through the first gate insulating film and the second gate insulating film; a fourth gate electrode provided to the second semiconductor layer across from the base substrate through the third gate insulating film; the interlayer insulating film provided to cover the fourth gate electrode; and a third terminal electrode and a fourth terminal electrode provided on the interlayer insulating film and spaced apart from each other, formed of a same material as, and in a same layer as, the third metal layer, and respectively and electrically connected to the third conductor region and the fourth conductor region.

11. The display device according to claim 10,
wherein the thin-film transistor layer includes: a first protective insulating film provided on the first terminal electrode, the second terminal electrode, the third terminal electrode, and the fourth terminal electrode; a first planarization film provided on the first protective insulating film; the third metal layer provided on the first planarization film; a second protective insulating film provided on the third metal layer; and a second planarization film provided on the second protective insulating film, and
the third terminal electrode and the fourth terminal electrode are electrically connected to a corresponding pixel electrode included in the plurality of pixel electrodes, through: a contact hole formed in the first protective insulating film and the first planarization film; a first relay electrode provided between the first planarization film and the second protective insulating film, and formed of a same material as, and in a same layer as, the first metal layer; a contact hole formed in the second protective insulating film; a second relay electrode provided between the second protective insulating film and the second planarization film, and formed of a same material as, and in a same layer as, the terminal protective layer; and a contact hole formed in the second planarization film.

12. The display device according to claim 1, further comprising
a sealing film provided to cover the light-emitting element layer.

13. The display device according to claim 1,
wherein each of the plurality of light-emitting functional layers is an organic electroluminescence layer.

14. The display device according to claim 7, further comprising
A sealing film provided to cover the light-emitting element layer.

15. The display device according to claim 7,
wherein each of the plurality of light-emitting functional layers is an organic electroluminescence layer.
